(19) United States
(12) Patent Application Publication
(10) Pub. No.: US 2024/0055476 A1
(43) Pub. Date: Feb. 15, 2024

(54) Isolation Structures in Semiconductor Devices

(71) Applicant: Taiwan Semiconductor Manufacturing Company, Ltd., Hsin-Chu (TW)

(72) Inventors: Cheng-Wei Chang, Taipei City (TW); Shahaji B. More, Hsinchu City (TW); Lun-Kuang Tan, Hsinchu City (TW); Chi-Yu Chou, Hsinchu County (TW); Yueh-Ching Pai, Taichung City (TW)

(21) Appl. No.: 18/298,277

(22) Filed: Apr. 10, 2023

Related U.S. Application Data
(60) Provisional application No. 63/382,146, filed on Nov. 3, 2022.
(60) Provisional application No. 63/397,355, filed on Aug. 11, 2022.

(51) Int. Cl. H01L 29/06; H01L 27/092; H01L 21/8238; H01L 29/66; H01L 29/423; H01L 29/775; H01L 29/786

(52) U.S. Cl. CPC H01L 29/0649; H01L 27/092; H01L 21/823807; H01L 21/823878; H01L 29/66545; H01L 29/0673; H01L 29/42392; H01L 29/775; H01L 29/66439; H01L 29/78696

(57) ABSTRACT

A method of fabricating a semiconductor device includes providing a dummy structure that includes channel layers, inner spacers disposed between adjacent ones of the channel layers, and a gate structure extending lengthwise in a first direction. A first trench extending lengthwise perpendicular to the first direction is formed, which divides the gate structure into segments. A first isolation feature is deposited in the first trench. The method also includes etching the gate structure and the channel layers to form a second trench extending lengthwise in the first direction. The second trench exposes the inner spacers. A second isolation feature is deposited in the second trench. The second isolation feature intersects the first isolation feature in a top view of the semiconductor device.

### PRIORITY DATA

This application claims the benefit of U.S. Provisional Application No. 63/397,355, filed Aug. 11, 2022, and U.S. Provisional Application No. 63/382,146, filed Nov. 3, 2022, which are hereby incorporated by references in their entirety.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far these goals have been achieved in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFETs and GAA devices are compatible with conventional complementary metal-oxide-semiconductor (CMOS) processes and their three-dimensional structure allows them to be aggressively scaled while maintaining gate control and mitigating SCEs.

However, as the minimum feature sizes are reduced, additional problems, such as merging of adjacent source/drain epitaxial features and merging of adjacent gate structures, arise that should be addressed. Therefore, although existing approaches in semiconductor fabrication have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified top-down layout view of a multi-gate device, according to one or more aspects of the present disclosure.

FIG. 2 is a flow chart of a method of fabricating a multi-gate device, according to one or more aspects of the present disclosure.

FIGS. 3A, 4A, 5A, 6A, 7A, 8A, 9A, 10A, 11A, 12A, and 13A provide cross-sectional views of an embodiment of a semiconductor device along a plane substantially parallel to a plane defined by a cutline A-A of FIG. 1 at various stages of the method of FIG. 2, according to one or more aspects of the present disclosure.

FIGS. 3B, 4B, 5B, 6B, 7B, 8B, 9B, 10B, 11B, 12B, and 13B provide cross-sectional views of an embodiment of a semiconductor device along a plane substantially parallel to a plane defined by a cutline B-B of FIG. 1 at various stages of the method of FIG. 2, according to one or more aspects of the present disclosure.

FIGS. 3C, 4C, 5C, 6C, 7C, 8C, 9C, 10C, 11C, 12C, and 13C provide cross-sectional views of an embodiment of a semiconductor device along a plane substantially parallel to a plane defined by a cutline C-C of FIG. 1 at various stages of the method of FIG. 2, according to one or more aspects of the present disclosure.

FIGS. 3D, 4D, 5D, 6D, 7D, 8D, 9D, 10D, 11D, 12D, and 13D provide cross-sectional views of an embodiment of a semiconductor device along a plane substantially parallel to a plane defined by a cutline D-D of FIG. 1 at various stages of the method of FIG. 2, according to one or more aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure presents embodiments in the form of multi-gate transistors. Multi-gate transistors include those transistors whose gate structures are formed on at least two-sides of a channel region. These multi-gate devices may include a P-type metal-oxide-semiconductor device or an N-type metal-oxide-semiconductor multi-gate device. Specific examples may be presented and referred to herein as FINFET, on account of their fin-like structure. Also presented herein are embodiments of a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanowires/nanosheets) associated with a single, contiguous gate structure. However, one of ordinary skill would recognize that the teaching can apply to a single channel (e.g., single nanowire/nanosheet) or any number of channels. One of ordinary skill may recognize other examples of semiconductor devices that may benefit from aspects of the present disclosure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include isolation structures and related methods to isolate adjacent source/drain regions and isolate adjacent metal gate structures.

Continuing to provide the desired scaling and increased density for multi-gate devices in advanced technology nodes calls for scaling of the contacted poly pitch (CPP) (or “gate pitch”) and active region pitch (or “fin pitch”). In some embodiments of the present disclosure, a cut-poly (CPO) process is used to scale the CPP, and a cut-metal-gate (CMG) process is used to scale the fin pitch. For purposes of this disclosure, a “diffusion edge” may be equivalently referred to as an active edge, where for example an active edge abuts adjacent active regions. Further, an active region includes a region where transistor structures are formed (e.g., including source, drain, and gate/channel structures). In some examples, active regions may be disposed between insulating regions. The CPO process may provide an isolation feature (also referred to as CPO feature) between neighboring gate structures, and thus neighboring transistors, by performing a selective etching process along an active edge (e.g., at a boundary of adjacent active regions) to form a cut region and filling the cut region with dielectric material(s). The CPO feature prevents adjacent metal gate structures from merging. On the other hand, the CMG process may provide another isolation feature (also referred to as CMG feature) extending from gate regions into proximal source/drain regions, by performing a selective etching process to form a trench that divides a gate structure and filling the trench with dielectric material(s). The CMG feature divides the gate structure into segments and also prevents adjacent source/drain epitaxial features (or simplified as source/drain features) from merging. Other embodiments and advantages will be evident to those skilled in the art upon reading the present disclosure.

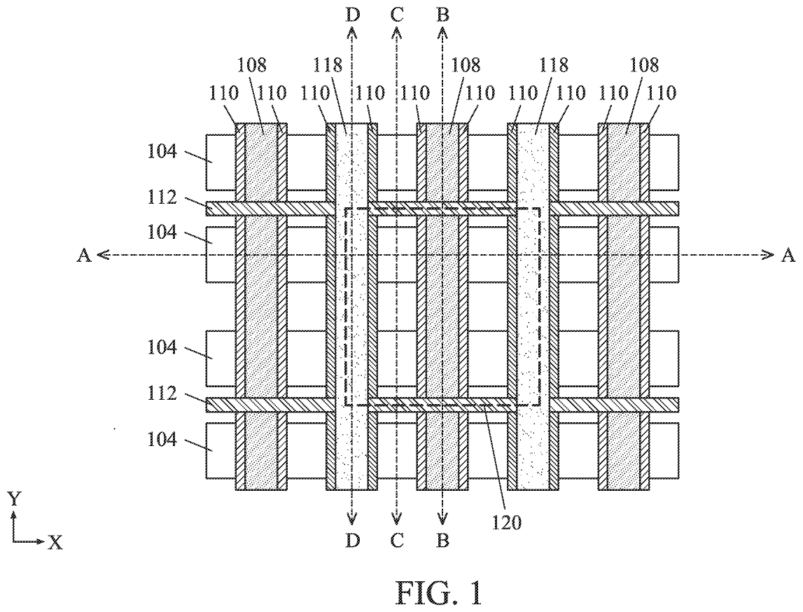

For purposes of the discussion that follows, FIG. 1 provides a simplified top-down layout view of an intermediate structure in forming a multi-gate device 100, according to some embodiments. In various embodiments, the multi-gate device 100 may include a FinFET device, a GAA transistor, or other type of multi-gate device. The multi-gate device 100 may include a plurality of fin-shape elements (or referred to as fin elements, or fins) 104 extending from a substrate, a plurality of gate structures 108 disposed over and around the fin-shape elements 104, and a gate spacer layer 110 disposed on sidewalls of each gate structure 108. The multi-gate device 100 may include a plurality of cut-metal-gate (CMG) features 112 dividing one or more gate structures 108 into segments. FIG. 1 further illustrates cut-poly (CPO) features 118 formed in deep trenches and intersecting the CMG features 112. The term “intersecting” (or “intersect”, “intersection”) in the present disclosure refers to a configuration that in a top view two features traveling through each other.

In the illustrated embodiment, the CMG features 112 extend lengthwise along the X-direction with a width along the Y-direction, and the CPO features 118 extend lengthwise along the Y-direction with a width along the X-direction that is larger than the width of the CMG feature 112. Alternatively, the width of the CPO features 118 may be equal or smaller than the width of the CMG feature 112. The CMG features 112 and CPO features 118 form a grid of cells. Each cell (e.g., cell 120 denoted in FIG. 1) has two opposing edges defined by two CPO features 118 and another two opposing edges defined by two CMG features 112. The one or more transistors formed in the cell are isolated from surrounding transistors, with less risk of having source/drain features and gate structures merged with adjacent features.

Although four fins 104 are illustrated in FIG. 1 and in the following figures, it is understood that depending on the desired design and the number of multi-gate transistors, any suitable number of fins 104 may be formed in the multi-gate device 100. Furthermore, any suitable number of gate structures 108, CMG features 112, CPO features 118 may be formed to implement the desired multi-gate device 100.

In some embodiments, the gate structures 108 may have curved portions (curved sidewalls) with larger width at intersections with the fin-shape elements 104, which is further illustrated in FIG. 14A. In furtherance of embodiments, the CMG features 112 may also have curved portions (curved sidewalls) with larger width at intersections with the gate structures 108, which is further illustrated in FIG. 14B. In FIGS. 14A and 14B, the inner spacers 319 omitted in FIG. 1 are also depicted. The inner spacers 319 may also have curved sidewalls.

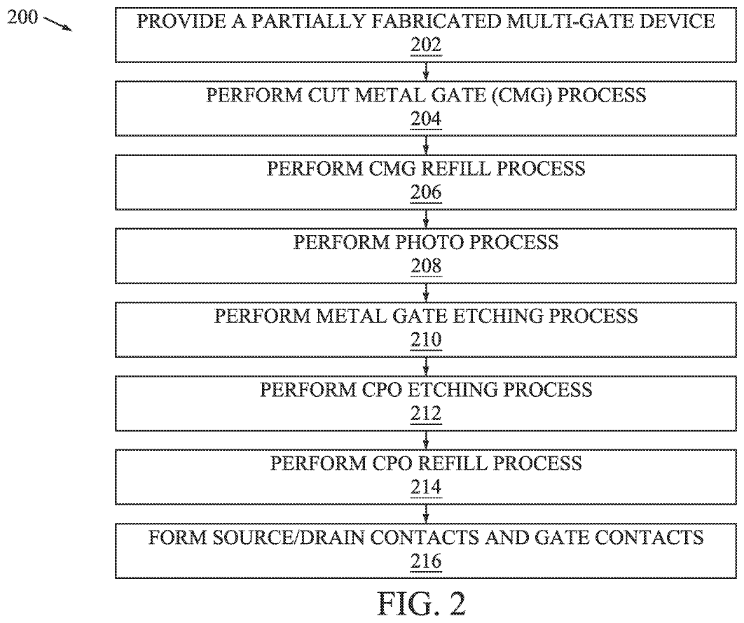

Referring back to FIG. 1, FIG. 1 further illustrates a first cutline (A-A), a second cutline (B-B), a third cutline (C-C), and a fourth cutline (D-D) taken through the intermediate structure. The first cutline (A-A) is taken through the length of one of the fins 104 and through the three gate structures 108 and two CPO features 118. The second cutline (B-B) is taken through the length of one of the gate structures 108 and through the two CMG features 112. The third cutline (C-C) is taken through source/drain regions disposed between one of the gate structures 108 and one of the CPO features 118, and through the two CMG features 112. The fourth cutline (D-D) is taken through the length of one of the CPO features 118. Channel regions of the multi-gate device 100, which may include a plurality of semiconductor channel layers (e.g., when the multi-gate device 100 includes GAA transistors), are disposed within the fins 104, underlying the gate structures 108, along a plane substantially parallel to a plane defined by the first cutline (A-A) of FIG. 1. Various other features of the multi-gate device 100 are discussed in more detail below with reference to the method of FIG. 2.

Referring to FIG. 2, illustrated therein is a method 200 of fabrication of a semiconductor device (or device) 300 (e.g., which includes a multi-gate device) using a combination of CMG process and CPO process, in accordance with various embodiments. The method 200 is discussed below with reference to a GAA device having a channel region that may be referred to as a nanosheet and which may include various geometries (e.g., cylindrical, bar-shaped) and dimensions. However, it will be understood that aspects of the method 200, including the disclosed CMG process and CPO process, may be equally applied to other types of multi-gate devices (e.g., such as FinFETs or devices including both GAA devices and FinFETs) without departing from the scope of the present disclosure. In some embodiments, the method 200 may be used to fabricate the multi-gate device 100, described above with reference to FIG. 1. Thus, one or more aspects discussed above with reference to the multi-gate device 100 may also apply to the method 200. It is understood that the method 200 includes steps having features of a complementary metal-oxide-semiconductor (CMOS) technology process flow and thus, are only described briefly herein. Also, additional steps may be performed before, after, and/or during the method 200.

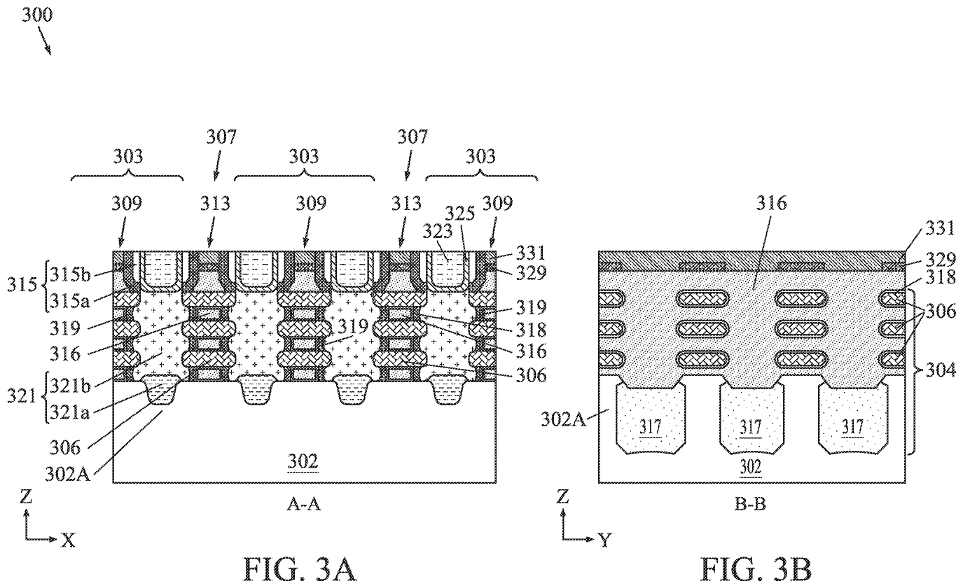

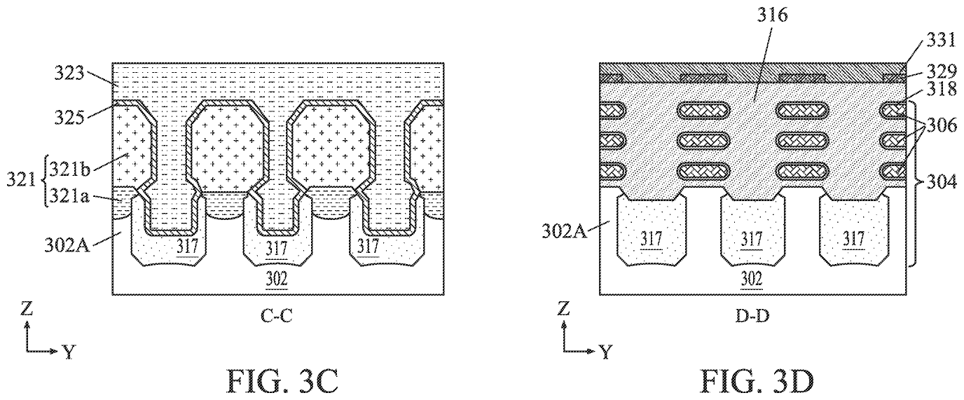

The method 200 is described below with reference to FIGS. 3A-13D which illustrate the device 300 at various stages of fabrication according to the method 200. The device 300 may be substantially similar to the device 100 in some embodiments. FIGS. 3A, 4A, 5A, 6A, 7A, 8A, 9A, 10A, 11A, 12A, and 13A provide cross-sectional views of the device 300 along the first cutline (A-A) of FIG. 1. FIGS. 3B, 4B, 5B, 6B, 7B, 8B, 9B, 10B, 11B, 12B, and 13B provide cross-sectional views of the device 300 along the second cutline (B-B) of FIG. 1. FIGS. 3C, 4C, 5C, 6C, 7C, 8C, 9C, 10C, 11C, 12C, and 13C provide cross-sectional views of the device 300 along the third cutline (C-C) of FIG. 1. FIGS. 3D, 4D, 5D, 6D, 7D, 8D, 9D, 10D, 11D, 12D, and 13D provide cross-sectional views of the device 300 along the fourth cutline (D-D) of FIG. 1.

Further, the device 300 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the inventive concepts of the present disclosure. In some embodiments, the device 300 includes a plurality of semiconductor devices (e.g., transistors), including PFETs, NFETs, etc., which may be interconnected. Moreover, it is noted that the process steps of method 200, including any descriptions given with reference to the figures are merely exemplary and are not intended to be limiting beyond what is specifically recited in the claims that follow.

The method 200 begins at block 202 (FIG. 2) where a partially fabricated multi-gate device is provided. Referring to FIGS. 3A-3D, in an embodiment of block 202, a device 300 includes active regions 303 and active edges 307 that each is defined at a boundary between two adjacent active regions 303. In some embodiments, the active regions 303 each include a GAA device 309, and the active edges 307 each include a dummy GAA structure 313, as described below. In accordance with embodiments of the present disclosure, a CPO process may provide an isolation region between the active regions 303, and thus between two adjacent GAA devices 309, by performing a CPO etching process along the active edges 307 to form cut-poly regions and filling the cut-poly regions with dielectric material(s) to form isolation features, as described in more detail below.

Each of the GAA device 309 and the dummy GAA structure 313 is formed on a substrate 302 having a fin-shape element (or referred to as fin) 304. In some embodiments, the substrate 302 may be a semiconductor substrate such as a silicon substrate. The substrate 302 may include various layers, including conductive or insulating layers formed on a semiconductor substrate. The substrate 302 may include various doping configurations depending on design requirements as is known in the art. The substrate 302 may also include other semiconductors such as germanium, silicon carbide (SiC), silicon germanium (SiGe), or diamond. Alternatively, the substrate 302 may include a compound semiconductor and/or an alloy semiconductor. Further, the substrate 302 may optionally include an epi layer, may be strained for performance enhancement, may include a silicon-on-insulator (SOI) structure, and/or have other suitable enhancement features.

The fin 304 may include a substrate portion 302A formed from the substrate 302 and nanosheet channel layers 306 above the substrate portion 302A. In some embodiments, the nanosheet channel layers 306 may include silicon (Si). However, in some embodiments, the nanosheet channel layers 306 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. By way of example, the nanosheet channel layers 306 may be epitaxially grown by a molecular beam epitaxy (MBE) process, a metalorganic chemical vapor deposition (MOCVD) process, and/or other suitable epitaxial growth processes. In some embodiments, a vertical spacing between adjacent nanosheet channel layers 306 is about 4 nm to about 8 nm.

It is noted that while the fins 304 are illustrated as including three (3) nanosheet channel layers 306, this is for illustrative purposes only and is not intended to be limiting beyond what is specifically recited in the claims. It can be appreciated that any number of nanosheet channel layers 306 can be formed, where for example, the number of nanosheet channel layers 306 depends on the desired number of channels for the GAA device (e.g., the device 300). In some embodiments, the number of nanosheet channel layers 306 is between 2 and 10.

Shallow trench isolation (STI) features 317 may also be formed interposing the fins 304. In some embodiments, the STI features 317 include SiO₂, silicon nitride, silicon oxynitride, fluorine-doped silicate glass (FSG), a low-k dielectric, combinations thereof, and/or other suitable materials known in the art. In various examples, the dielectric layer used to form the STI features 317 may be deposited by a CVD process, a subatmospheric CVD (SACVD) process, a flowable CVD process, an ALD process, a PVD process, and/or other suitable process.

In various examples, each of the GAA device 309 and the dummy GAA structure 313 of the device 300 further includes a gate structure 316, which may include a high-k/metal gate stack. In some embodiments, the gate structure 316 may form the gate associated with the multi-channels provided by the nanosheet channel layers 306 in the channel region of the GAA devices 309. The gate structure 316 may include a gate dielectric layer 318 that further includes an interfacial layer and a high-k dielectric layer formed over the interfacial layer. In some embodiments, the gate dielectric layer has a total thickness between about 1 nm and about 5 nm. High-k dielectrics, as used and described herein, include dielectric materials having a high dielectric constant, for example, greater than that of thermal silicon oxide (˜3.9). In some embodiments, the interfacial layer may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. In some examples, the interfacial layer includes the chemical oxide layer, discussed above. The high-k dielectric layer may include a high-k dielectric material such as hafnium oxide (HfO₂). Alternatively, the high-k dielectric layer may include other high-k dielectric materials, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The high-k dielectric layer may be formed by ALD, physical vapor deposition (PVD), CVD, oxidation, and/or other suitable methods.

The gate structure 316 may further include a metal electrode having a metal layer formed over the gate dielectric layer (e.g. over the interfacial layer and the high-k dielectric layer). The metal electrode may include a metal, metal alloy, or metal silicide. The metal electrode may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the metal layer may include Ti, Ag, Al, TiAlN, TaC, TaCN, TaSiN, Mn, Zr, TiN, TaN, Ru, Mo, Al, WN, Cu, W, Re, Ir, Co, Ni, other suitable metal materials or a combination thereof. In various embodiments, the metal layer may be formed by ALD, PVD, CVD, e-beam evaporation, or other suitable process. Further, the metal layer may be formed separately for N-type and P-type transistors which may use different metal layers. In addition, the metal layer may provide an N-type or P-type work function, may serve as a transistor gate electrode, and in at least some embodiments, the metal layer may include a polysilicon layer. The gate structure 316 includes portions that wrap around each of the nanosheet channel layers 306 of the fins 304, where the nanosheet channel layers 306 each provide semiconductor channel layers for the respective GAA device 309.

In some embodiments, a metal layer 329 may be formed over the metal layer of the gate structures 316, as shown. In some embodiments, the metal layer 329 includes selectively-grown tungsten (W), although other suitable metals may also be used. In at least some examples, the metal layer 329 includes a fluorine-free W (FFW) layer. In various examples, the metal layer 329 may serve as an etch-stop layer and may also provide reduced contact resistance (e.g., to the metal layer of the gate structures 316).

In some embodiments, a capping layer 331 may further be formed over the metal layer 329. In some embodiments, the capping layer 331 includes silicon (Si). However, in some examples, the capping layer 331 may include a dielectric material such as silicon oxide, silicon nitride, silicon carbide, silicon oxynitride, combinations thereof, or another suitable material.

In some embodiments, a gate spacer layer 315 may be formed on sidewalls of a top portion of the gate structure 316 of each of the GAA devices 309 and the dummy GAA structures 313. In some cases, the gate spacer layer 315 may have a thickness of about 2-10 nm. The gate spacer layer 315 may be formed prior to formation of the high-k/metal gate stack of the gate structure 316. For example, in some cases, the gate spacer layer 315 may be formed on sidewalls of a previously formed dummy (sacrificial) gate stack that is removed and replaced by the high-k/metal gate stack, described above, as part of a replacement gate (gate-last) process. In some embodiments, the gate spacer layer 315 includes multiple layers. In an exemplary embodiment, the gate spacer layer 315 is formed by first conformally depositing a conformal first gate spacer layer 315a over the device 300, then conformally depositing a second gate spacer layer 315b over the deposited first gate spacer layer 315a. The first gate spacer layer 315a may be formed of a nitride, such as silicon nitride, silicon oxynitride, silicon carbide, silicon carbonitride, the like, or a combination thereof, and may be formed using, e.g., a thermal oxidation, CVD, or other suitable deposition process. The second gate spacer layer 315b may be formed of silicon nitride, SiCN, a combination thereof, or the like using a suitable deposition method. Next, an anisotropic etch process, such as a dry etch process, is performed to remove horizontal portions of the first and second gate spacer layers 315a and 315b, leaving remaining portions on the sidewalls of the gate structures 316 as the gate spacer layer 315. The anisotropic etch process may also removes a top portion of the STI features 317 disposed outside of the gate structure 316 due to limited etching selectivity, such that a top portion of the STI features 317 may be recessed below the substrate portion 302A of the fins 304 (FIG. 3C).

In various examples, each of the GAA devices 309 and the dummy GAA structures 313 of the device 300 further includes inner spacers 319. The inner spacers 319 may be disposed between adjacent channels of the nanosheet channel layers 306, at lateral ends of the nanosheet channel layers 306, and in contact with portions of the gate structure 316 that interpose each of the nanosheet channel layers 306. In some examples, the inner spacers 319 may include silicon oxide, silicon nitride, silicon carbide, silicon oxynitride, SiCN, silicon oxycarbide, SiOCN, a low-k material, and/or combinations thereof. In various examples, the inner spacers 319 may extend beneath the gate spacer layer 315, described above, while abutting adjacent source/drain features 321, described below.

In some embodiments, source/drain features 321 are formed in source/drain regions adjacent to and on either side of the gate structure 316 of each of the GAA devices 309 and over the substrate portion 302A. As a result, the dummy GAA structure 313 is disposed between a first source/drain feature 321 of one of the GAA devices 309 (in one active region 303) and a second source/drain feature 321 of the another of the GAA devices 309 (in another active region 303). As shown, the source/drain features 321 are in contact with the inner spacers 319 and the nanosheet channel layers 306 of the respective GAA devices 309. Moreover, the source/drain features 321 disposed on either side of the dummy GAA structure 313 are in contact with the inner spacers 319 and the nanosheet channel layers 306 of the respective dummy GAA structure 313.

In various examples, the source/drain features 321 include semiconductor epi layers such as Ge, Si, GaAs, AlGaAs, SiGe, GaAsP, SiP, or other suitable material, which may be epitaxially grown from recessed substrate portion 302A of the fins 304 in the source/drain regions by one or more epitaxial processes. Further, the source/drain features 321 may include an undoped lower portion 321a and a doped upper portion 321b. In some embodiments, the doped upper portion 321b of the source/drain features 321 may be in-situ doped during the epi process. For example, in some embodiments, epitaxially grown SiGe source/drain features may be doped with boron. In some cases, epitaxially grown Si source/drain features may be doped with carbon to form Si:C source/drain features, phosphorous to form Si:P source/drain features, or both carbon and phosphorous to form SiCP source/drain features. In some embodiments, the doped upper portion 321b of the source/drain features 321 is not in-situ doped, and instead an implantation process is performed to dope the upper portion of the source/drain features 321. In some embodiments, formation of the source/drain features 321 may be performed in separate processing sequences for each of N-type and P-type source/drain features.

An inter-layer dielectric (ILD) layer 323 may also be formed over the device 300. In some embodiments, a contact etch stop layer (CESL) 325 is formed over the device 300 prior to forming the ILD layer 323. In some examples, the CESL 325 includes a silicon nitride layer, silicon oxide layer, a silicon oxynitride layer, and/or other materials known in the art. The CESL 325 may be formed by plasma-enhanced chemical vapor deposition (PECVD) process and/or other suitable deposition or oxidation processes. In some embodiments, the ILD layer 323 includes materials such as tetraethylorthosilicate (TEOS) oxide, un-doped silicate glass, or doped silicon oxide such as borophosphosilicate glass (BPSG), FSG, phosphosilicate glass (PSG), boron doped silicon glass (BSG), and/or other suitable dielectric materials. The ILD layer 323 may be deposited by a PECVD process or other suitable deposition technique. In some embodiments, after depositing the ILD layer 323, a planarization process, such as a chemical mechanical polishing (CMP) process, may be performed to remove excess material and planarize a top surface of the device 300.

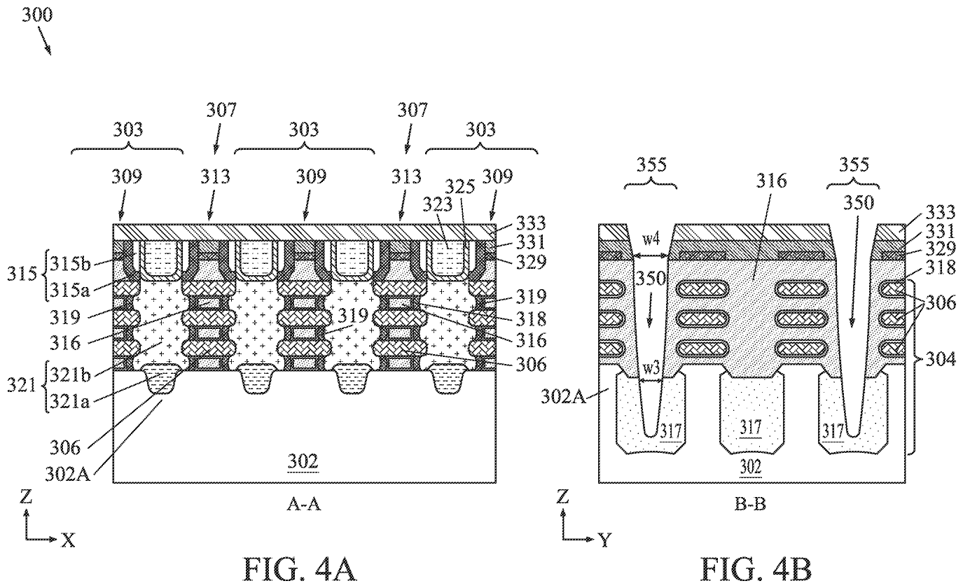

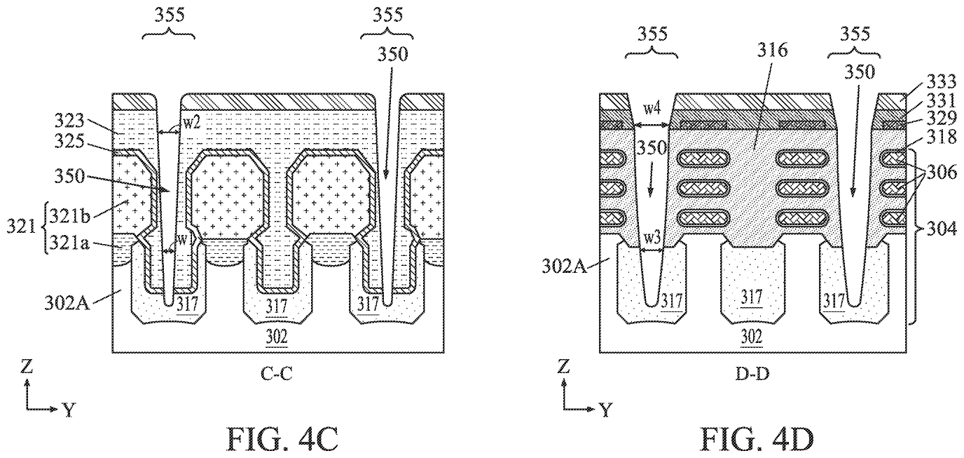

The method 200 then proceeds to block 204 (FIG. 2) where a cut metal gate (CMG) process is performed. With reference to FIGS. 4A-4D, in an embodiment of block 204, a hard mask layer 333 is formed over the device 300. Any suitable material or composition may be used in forming the hard mask layer 333, such as a tri-layer hard mask in one example. The example hard mask layer 333 includes a bottom layer, a middle layer, and a top layer (not shown), each with different or at least independent materials. The bottom layer may include tetraethyl orthosilicate (TEOS), a nitrogen free anti-reflective coating (NFAARC) film, oxygen-doped silicon carbide (ODC), silicon carbon nitride (SiCN), or plasma-enhanced oxide (PEOx); the middle layer may include a silicon rich polymer material (e.g., SiCxHyOz); the top layer may include tetraethyl orthosilicate (TEOS) or silicon oxide. It is understood that in other embodiments, one or more layers may be omitted and that additional layers may be provided as a part of the tri-layer hard mask. After forming the hard mask layer 333, a CMG process is performed to isolate the gate structures 316 of adjacent structures. By way of example, a photolithography and etch process may be performed to etch portions of the hard mask layer 333, and use the etched hard mask layer 333 as an etching mask to further etch the capping layer 331, the metal layer and the gate dielectric layer of the gate structures 316, and a top portion of the STI features 317 to form trenches 350 in cut metal gate regions 355.

The trenches 350 extend downwardly through space between adjacent metal layers 329 (FIG. 4B) and extend into adjacent source/drain regions (FIG. 4C). In a top view, one trench 350 may extend lengthwise along the X-direction cutting through multiple gate structures 316 (e.g., feature 112 in FIG. 1). In some embodiments (not depicted), due to the ever-decreasing fin pitch, adjacent source/drain features 321 may have measured into one bigger epitaxial feature when the device 300 is provided at block 202, and the trenches 350 divide the already-merged epitaxial feature into two separate source/drain features 321 and expose cut sidewalls of the divided source/drain features 321. In some embodiments, a bottom surface of the trenches 350 is below a top surface of the STI features 317. In various examples, the trenches 350 may be etched using a dry etch (e.g., reactive ion etching), a wet etch, or a combination thereof. Due to different etching rates when etching different regions, an opening of the trench 350 in the gate region may be wider than in the source/drain region. For example, an opening width at a bottom portion of the trench 350 in the source/drain region, denoted as W1, may range from about 5 nm to about 10 nm; an opening width at a top portion of the trench 350 in the source/drain region, denoted as W2, may range from about 8 nm to about 20 nm; an opening width at a bottom portion of the trench 350 in the gate region, denoted as W3, may range from about 10 nm to about 40 nm; and an opening width at a top portion of the trench 350 in the gate region, denoted as W4, may range from about 20 nm to about 50 nm, in some embodiments (i.e., W4>W2 and W3>W1). Further, a depth of the trench 350 in the source/drain region may be smaller than in the gate region. In other words, the bottom surface of the trench 350 may have a step profile, which is higher in the source/drain region and lower in the gate region. In the source/drain region, the bottom surface of the trench 350 may be above the bottom surface of the STI feature 317 for a distance of about 10 nm to about 30 nm; in the gate region, the bottom surface of the trench 350 may be above the bottom surface of the STI feature 317 for a distance of about 8 nm to about 25 nm. In the source/drain region, the bottom surface of the trench 350 may be below the bottom surface of the source/drain feature 321 for about 25 nm to about 55 nm. In the gate region, the bottom surface of the trench 350 may be below the bottom surface of the gate structure for about 30 nm to about 55 nm.

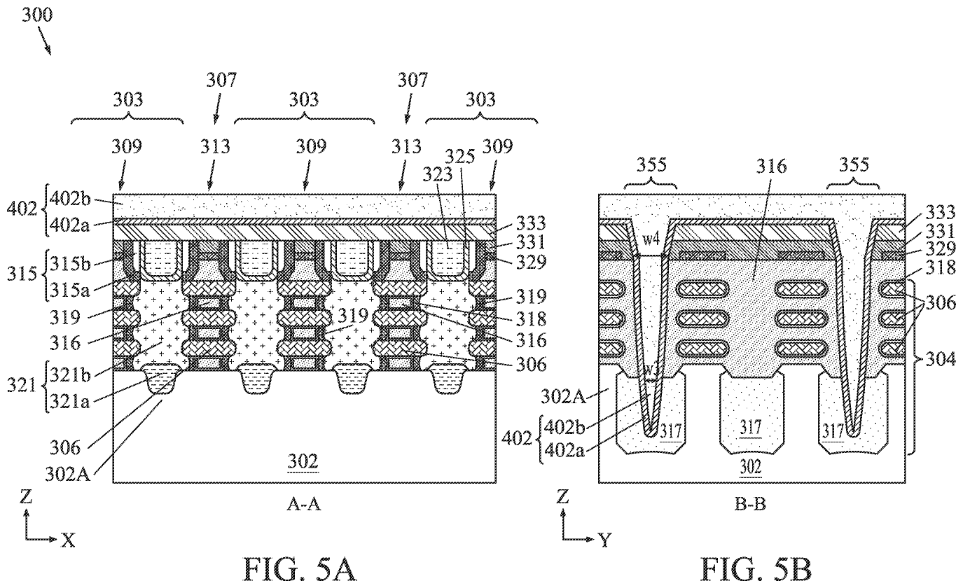

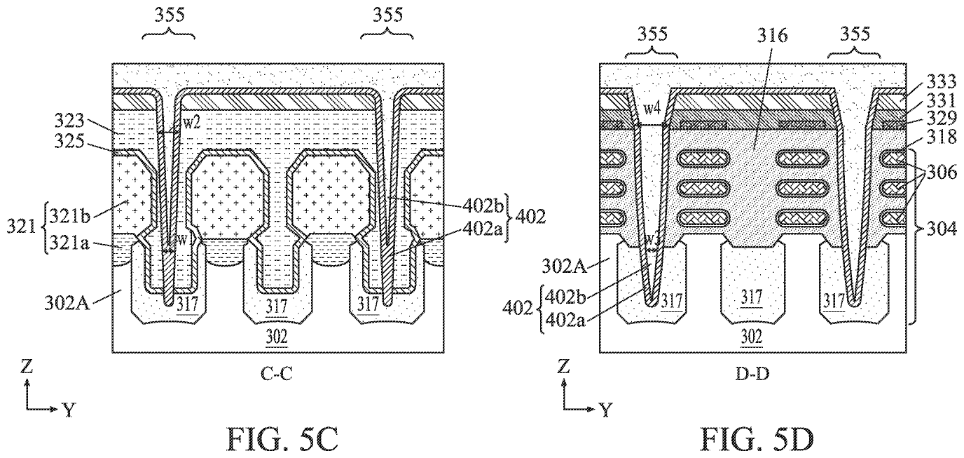

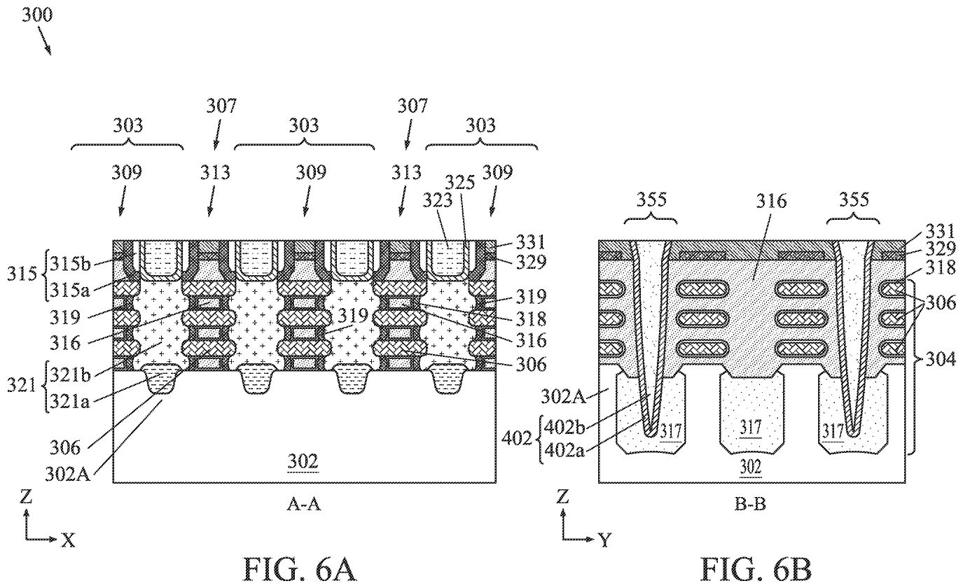

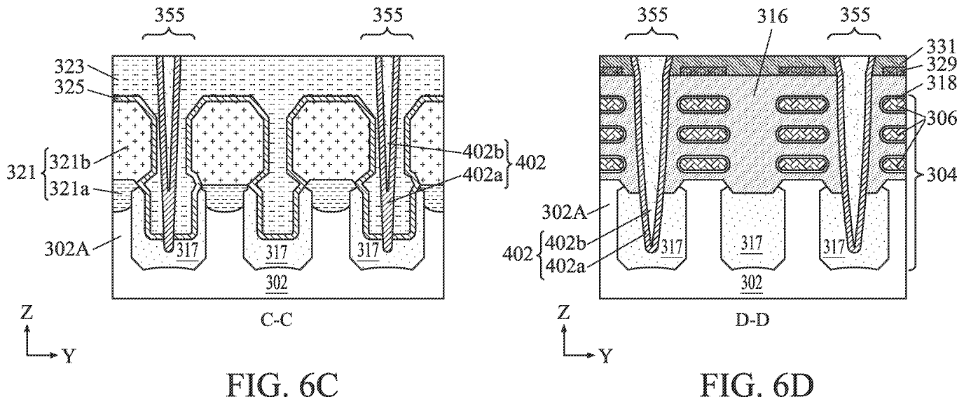

The method 200 then proceeds to block 206 (FIG. 2) where a CMG refill process is performed. With reference to FIGS. 5A-5D and 6A-6D, in an embodiment of block 206, a CMG refill process is used to form dielectric layer 402 over the device 300, including over the hard mask layer 333. The dielectric layer 402 also fills the previously formed trenches 350 and electrically isolate the gate structures 316 of adjacent structures and electrically isolate adjacent source/drain features 321. In some embodiments, the dielectric layer 402 includes a liner layer 402a and a dielectric layer 402b over the liner layer 402a. The liner layer 402a may be a nitride layer, for example including SiN. The dielectric layer 402b may include SiO₂, silicon oxynitride, FSG, a low-k dielectric, combinations thereof, and/or other suitable materials known in the art. Alternatively, the liner layer 402a may be an oxide layer, such as including SiO₂, and the dielectric layer 402b may be a nitride layer, such as including SiN. In various examples, the liner layer 402a may be conformally deposited by an ALD process, a CVD process, a PVD process, and/or other suitable process, and the dielectric layer 402b may be deposited by a CVD process, an SACVD process, a flowable CVD process, an ALD process, a PVD process, and/or other suitable process. Due to the narrow opening width at a bottom portion of the trench 350 in the source/drain region (W1), the liner layer 402a may fully fill the tip of the trench 350 in the source/drain region, such as shown in FIG. 5C. In other words, a liner layer 402a may be formed filling a bottom portion of the trench 350 in the source/drain regions. A top surface of the liner layer 402a (a bottom surface of the dielectric layer 402b) in the source/drain region may be above the STI features 317 (also the undoped lower portion 321a), as shown in FIG. 5C. If the source/drain features 321 were divided from a previously merged one as discussed above, the liner layer 402a is also in direct contact with exposed sidewalls of the source/drain features 321. In some cases, after depositing the dielectric layer 402, a planarization process, such as a CMP process, may be performed to remove excess material and planarize a top surface of the device 300. The hard mask layer 333 may also be removed. The resultant structure after the CMP process is shown in FIGS. 6A-6D. The remaining portions of the dielectric layer 402 filling the trenches 350 are also referred to as CMG features 402.

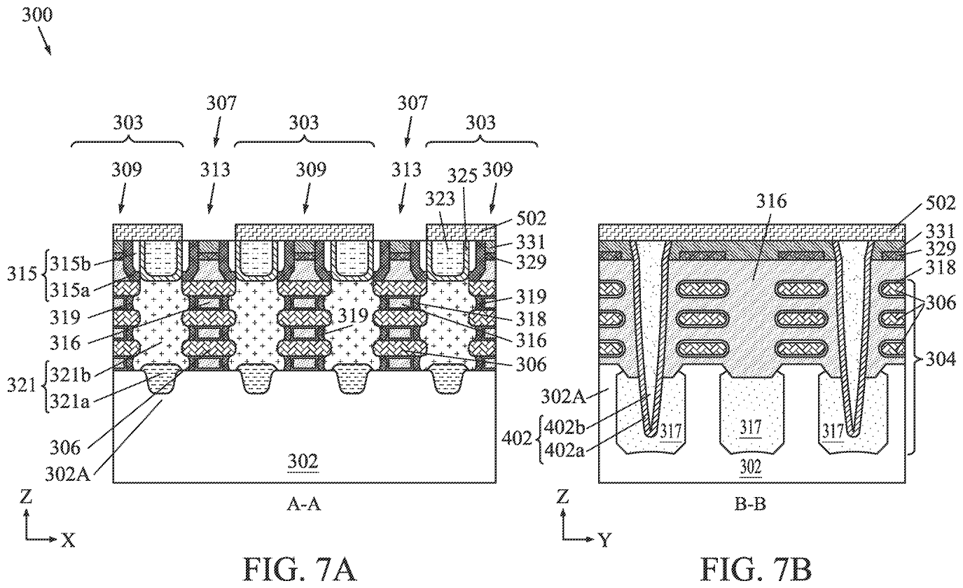

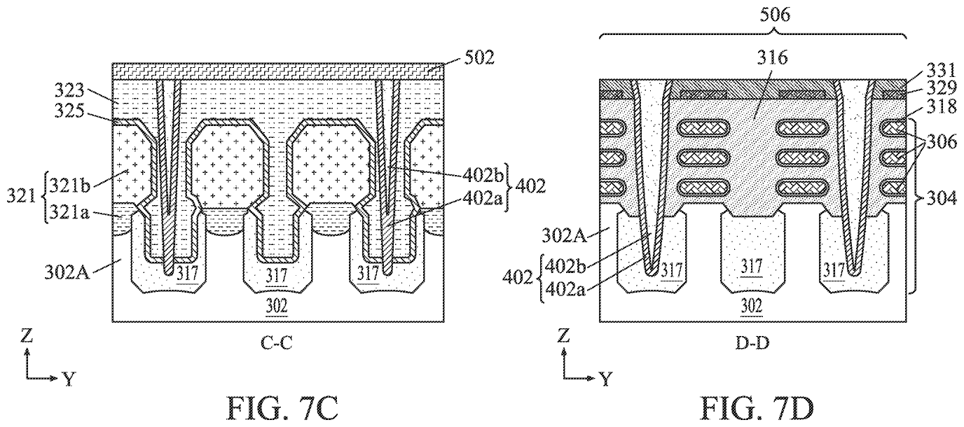

The method 200 then proceeds to block 208 (FIG. 2) where a photolithography (photo) process is performed. With reference to FIGS. 7A-7D, in an embodiment of block 208, a hard mask layer is formed over the device 300 and patterned to form a patterned mask layer 502 that exposes the dummy gate structures 313 located at the active edges 307. In various embodiments, the photo process used to form a patterned resist layer over the hard mask layer include soft baking, mask aligning, exposure, post-exposure baking, developing, rinsing, drying (e.g., spin-drying and/or hard baking), other suitable lithography processes, and/or combinations thereof. In some embodiments, the photo process of block 208 may include a CPO photo process, where the patterned mask layer 502 provides openings in a CPO region 506 that exposes top surfaces of the capping layer 331 and the gate spacer layer 315 (FIG. 7A) and top surfaces of the CMG features 402 (FIG. 7D). Due to the etching contrasts among various material layers, the etching process is self-aligned, such that the process window allows the openings in the patterned mask layer 502 to be enlarged to counter overlaying inaccuracy. Thus, a portion of the top surfaces of the CESL 325 and/or the ILD layer 323 may also be exposed in the openings. In addition, the CPO region 506 may include the active edge 307 and the dummy GAA structure 313, discussed above with reference to FIG. 3A.

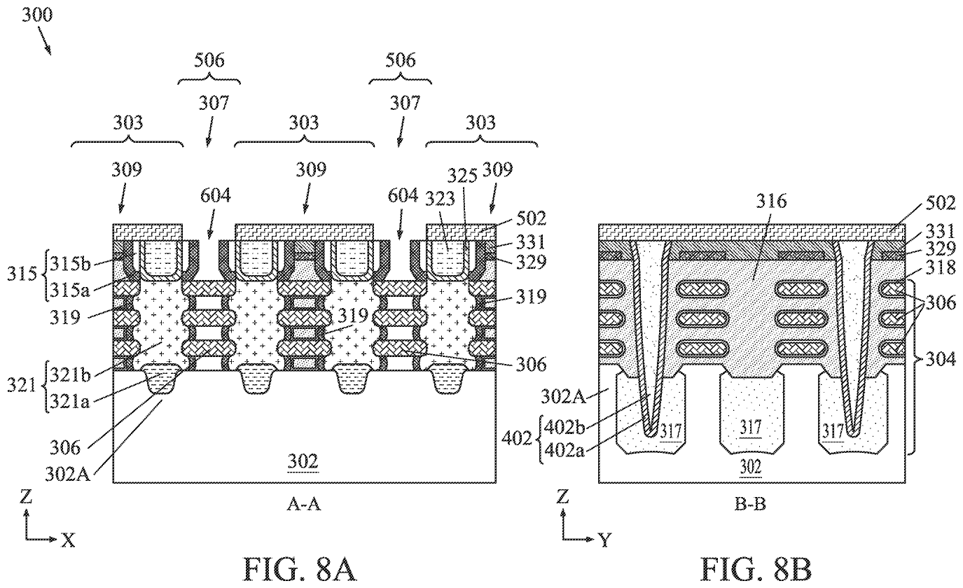

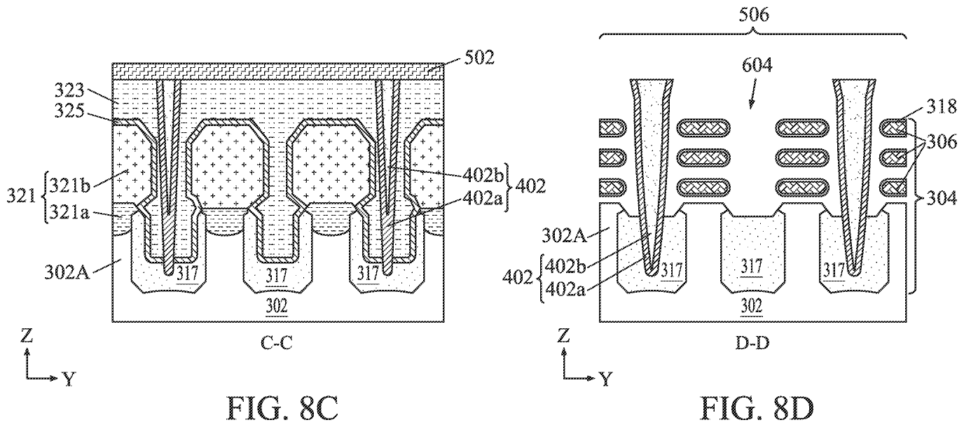

The method 200 then proceeds to block 210 (FIG. 2) where a metal gate etching process is performed. With reference to FIGS. 8A-8D, in an embodiment of block 210, the metal gate etching process includes removal of the capping layer 331, the metal layer 329, and the gate structure 316 from the dummy GAA structures 313 within the CPO region 506. The metal gate etching process may be performed through the openings in the patterned mask layer 502 in forming gate trenches 604. It is noted that the metal gate etching process may remove the gate structure 316 from a top portion of the dummy GAA structure 313, as well as between adjacent channels of the nanosheet channel layers 306. Thus, the gate trenches 604 is extended downwardly to a top surface of the substrate portion 302A of the fin 304 and a top surface of the STI features 317. The nanosheet channel layers 306 and the inner spacers 319 are also exposed in the gate trenches 604. In various embodiments, removal of the gate structure 316 may include a dry etching process, a wet etching process, and/or a combination thereof. In one example, the etching process is a wet etching process, which may include a combination of ammonium hydroxide (NH₄OH), hydrogen peroxide (H₂O₂), and water (H₂O). Due to the etching contrasts among various material layers, the etching process is self-aligned. Thus, the gate spacer layer 315 may also be exposed on sidewalls of the gate trenches 604, and the sidewalls of the CMG features 402 within the CPO region 506 are also exposed in the gate trenches 604. In the illustrated embodiment, after the metal gate etching process, the gate dielectric layer 318 may still remain on the nanosheet channel layers 306. After the etching process, and in a further embodiment of block 210, the patterned resist layer may be removed, for example, by way of a solvent, resist stripper, ashing, or other suitable technique.

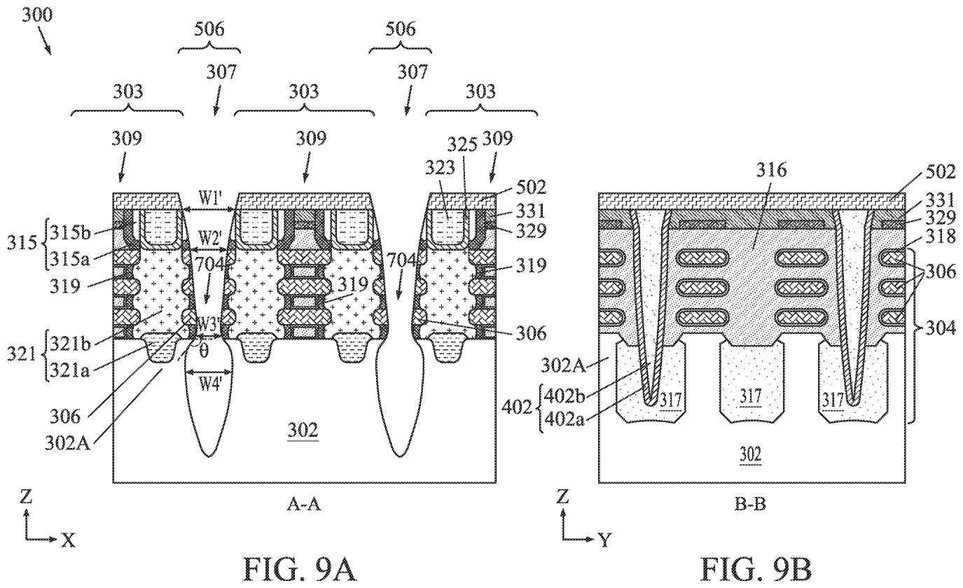

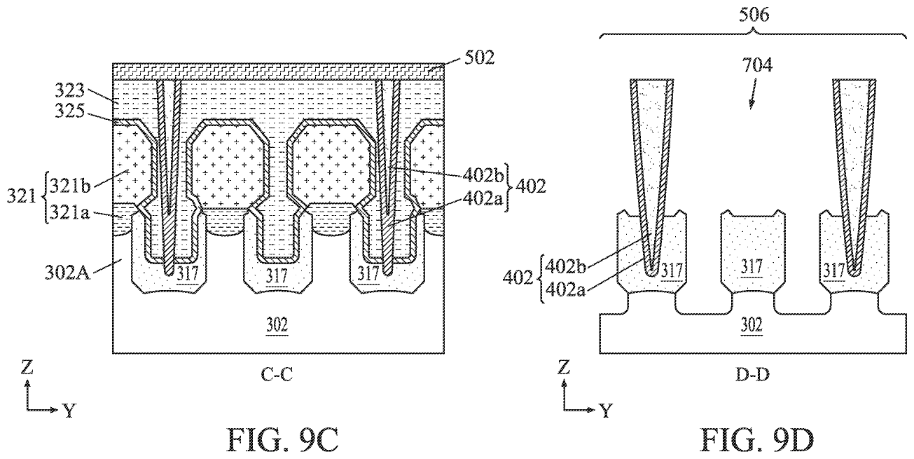

The method 200 then proceeds to block 212 (FIG. 2) where a CPO etching process is performed. With reference to FIGS. 9A-9D, in an embodiment of block 212, the CPO etching process etches the device 300 through the gate trenches 604 within the CPO region 506 to form trenches 704. The trenches 704 are also referred to as CPO trenches 704. In some cases, the CPO etching process includes a dry etch (e.g., reactive ion etching), a wet etch, or a combination thereof. In some embodiments, the CPO etching process removes the nanosheet channel layers 306 (and the gate dielectric layer 318 thereon) within the CPO region 506 and removes the substrate portion 302A of the dummy GAA structure 313, such that the trench 704 extends into the substrate 302 and is below a bottom surface of the STI features 317 (thus also below the bottom tip of the CMG feature 402). In some embodiments, the bottom of the trench 704 is below the bottom tip of the CMG feature 402 for about 10 nm to about 60 nm. The lateral ends of the nanosheet channel layers 306 interposing the inner spacers 319 may remain. The combination of the lateral ends of the nanosheet channel layers 306 and the inner spacers 319 covers the source/drain features 321 from exposing in the trenches 704. Also depicted in FIG. 9D, although the etching contrasts confine the trenches 704 between sidewalls of the CMG features 402 and the STI features 317, the trenches 704 may extend laterally when it extends in a depth below the bottom surface of the STI features 317, particularly in a wet etching process. In the depicted embodiment, a portion of the trenches 704 is directly under the STI features 317. Due to the limited etching contrasts, the topmost portion of the CMG features 402 may be recessed and exhibits rounded corners. Similarly, as depicted in FIG. 9A, due to the limited etching contrasts, the trenches 704 may extend laterally when it extends below the bottommost inner spacer 319, such that a portion of the trenches 704 is directly under the bottommost inner spacer 319. The gate spacer layer 315 may also suffer certain etching lost, such that the trenches 704 may have a profile of a wide opening, a narrow middle portion, an expanded bottom portion, and a bottom tip. In the depicted embodiment, an opening width at a top portion of the trench 704, denoted as W1′, may range from about 12 nm to about 50 nm; an opening width at the height of the topmost nanosheet channel layer 306, denoted as W2′, may decrease to about 10 nm to about 44 nm; the narrowest opening width (necking) being at the height of the bottommost inner spacer 319, denoted as W3′, may range from about 8 nm to about 30 nm; and the expanded opening width at the bottom portion of the trench 704, denoted as W4′, may range from about 12 nm to about 40 nm. In some embodiments, even the necking W3′ is wider than the width of the CMG feature 402 (W2/W4). In some embodiments, the necking W3′ is narrower than the width of the CMG feature 402 (W2/W4), but W1′, W2′, and W4′ are all larger than W2/W4. The expanded bottom portion may have a top curvature profile with a tangential line forming an angle, denoted as θ, that ranges from about 100° to about 150° with respect to a horizontal line.

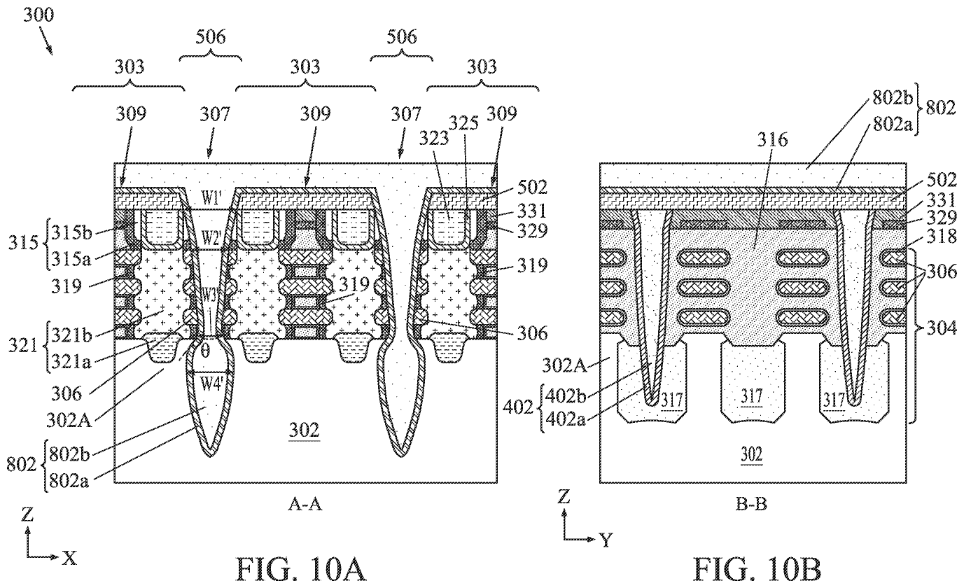

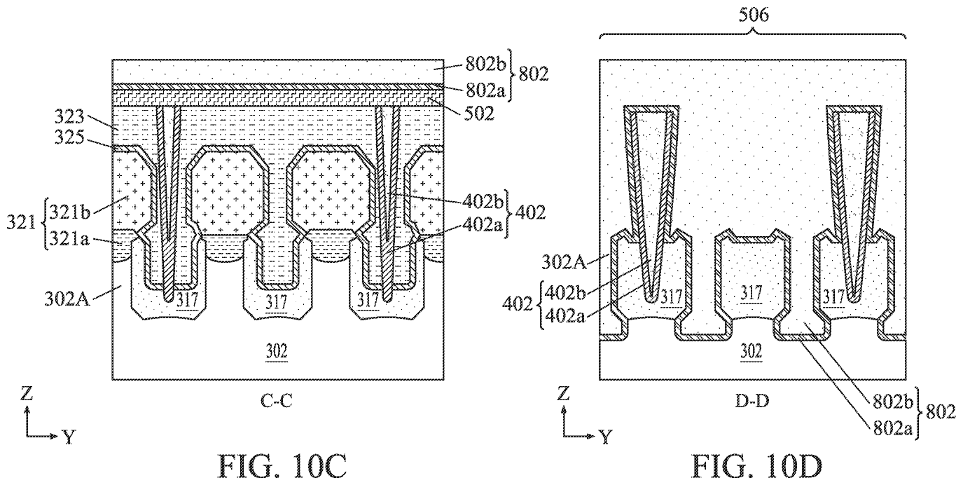

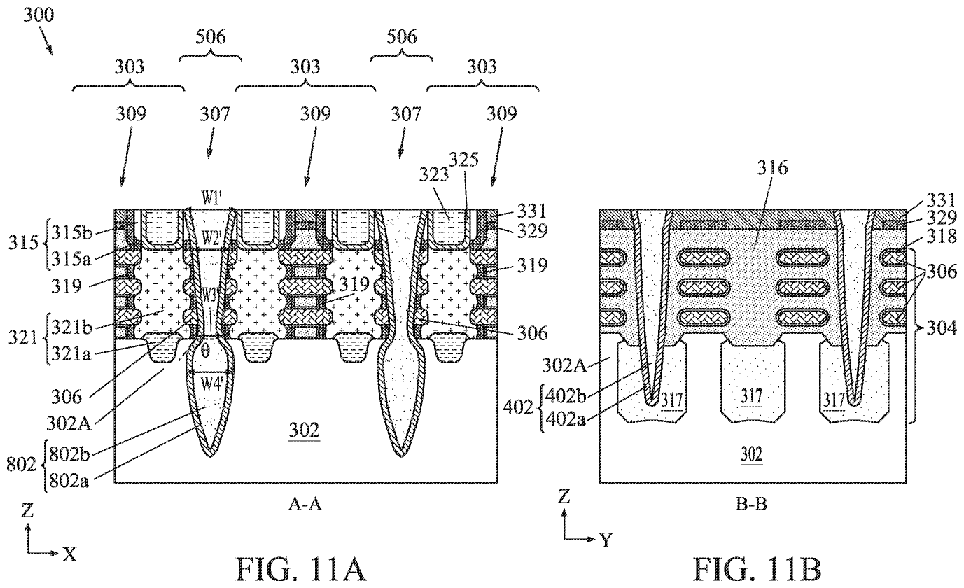

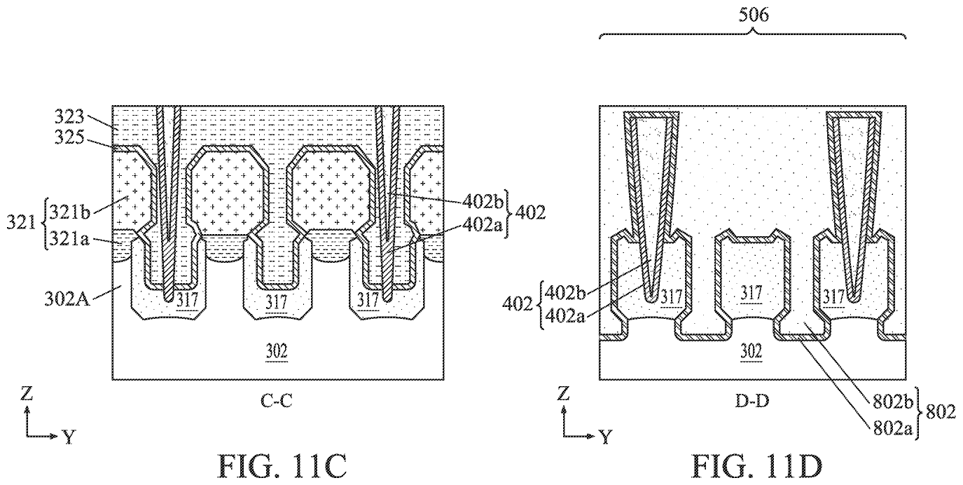

The method 200 then proceeds to block 214 (FIG. 2) where a CPO refill process is performed. With reference to FIGS. 10A-10D and 11A-11D, in an embodiment of block 214, a CPO refill process is used to form dielectric layer 802 over the device 300, including over the patterned mask layer 502. The dielectric layer 802 also fills the previously formed trenches 704. In some embodiments, the dielectric layer 802 includes a liner layer 802a and a dielectric layer 802b over the liner layer 802a. The liner layer 802a may be a nitride layer, for example including SiN. The dielectric layer 802b may include SiO₂, silicon oxynitride, FSG, a low-k dielectric, combinations thereof, and/or other suitable materials known in the art. Alternatively, the liner layer 802a may be an oxide layer, such as including SiO₂, and the dielectric layer 802b may be a nitride layer, such as including SiN. In various examples, the liner layer 802a may be conformally deposited by an ALD process, a CVD process, a PVD process, and/or other suitable process, and the dielectric layer 802b may be deposited by a CVD process, an SACVD process, a flowable CVD process, an ALD process, a PVD process, and/or other suitable process. Due to the partial etching loss of the top portion of the gate spacer layer 315, the CESL 325 may be exposed, and the liner layer 802a may be in direct contact with an exposed portion of the CESL 325. As depicted in FIG. 10D, the liner layer 802a covers the liner layer 402a and the top surface of the dielectric layer 402b. The material composition of the liner layers 402a and 402b may be the same, and the material composition of the dielectric layers 802a and 802b may be the same, in some embodiments. For example, the liner layers 402a and 402b are both a nitride, and the dielectric layers 802a and 802b are both an oxide; or, the liner layers 402a and 402b are both an oxide, and the dielectric layers 802a and 802b are both a nitride. Alternatively, the material composition of the liner layers 402a and 402b may be different, and the material composition of the dielectric layers 802b and 802b may be different, in some embodiments. For example, the liner layer 402a and the dielectric layer 802b are both a nitride, and the liner layer 802a and the dielectric layer 402b are both an oxide and form a continuous material layer; or, the liner layers 402a and the dielectric layer 802 are both an oxide, and the liner layer 802a and the dielectric layers 402b are both a nitride and form a continuous material layer. In some cases, after depositing the dielectric layer 802, a planarization process, such as a CMP process, may be performed to remove excess material and planarize a top surface of the device 300. The patterned mask layer 502 may also be removed. The resultant structure after the CMP process is shown in FIGS. 11A-11D. The remaining portions of the dielectric layer 802 filling the trenches 704 are also referred to as CPO features 802.

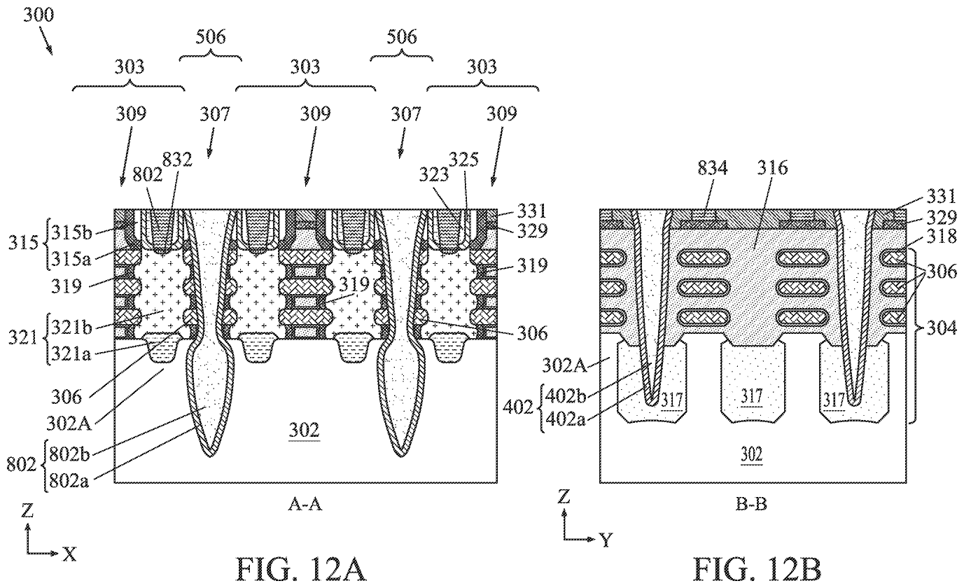

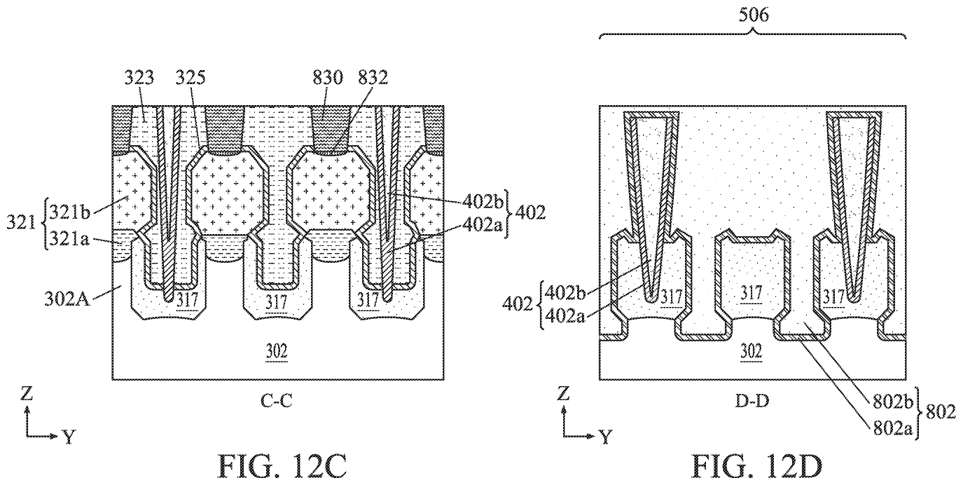

The method 200 then proceeds to block 216 (FIG. 2) where source/drain contacts and gate contacts are formed. With reference to FIGS. 12A-12D, in an embodiment of block 216, source/drain contacts 830 are formed that extend through the the ILD layer 323 and the CESL 325. The formation of the source/drain contacts 830 includes, for example but is not limited to: performing one or more etching processes to form contact openings extending through the ILD layer 323 and the CESL 325 to expose source/drain features 321; depositing one or more metallic materials that overfill the contact openings; a CMP process is then performed to remove excess metal material located outside the contact openings. The metallic materials may include tungsten (W), cobalt (Co), molybdenum (Mo), ruthenium (Ru), nickel (Ni), copper (Cu), or other metals, and may be formed by CVD, PVD, ALD, plating, or other suitable processes. In some embodiments, a silicide feature 832 is formed between the source/drain contacts 830 and the source/drain features 321 to further reduce contact resistance. In some embodiments, the silicide feature 832 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The formation of the gate contacts 834 includes, for example but is not limited to: performing one or more etching processes to form gate contact openings extending through the capping layer 331 to expose the metal layer 329; depositing one or more metallic materials that overfill the contact openings; a CMP process is then performed to remove excess metal material located outside the contact openings. The gate contacts 834 may include a conductive barrier layer and a bulk metal layer. The conductive barrier layer may include titanium (Ti), tantalum (Ta), tungsten (W), cobalt (Co), ruthenium (Ru), or a conductive nitride such as titanium nitride (TiN), titanium aluminum nitride (TiAlN), tungsten nitride (WN), tantalum nitride (TaN), or combinations thereof, and may be formed by CVD, PVD, ALD, and/or other suitable processes. The bulk metal layer may include tungsten (W), cobalt (Co), molybdenum (Mo), ruthenium (Ru), nickel (Ni), copper (Cu), or other metals, and may be formed by CVD, PVD, ALD, plating, or other suitable processes.

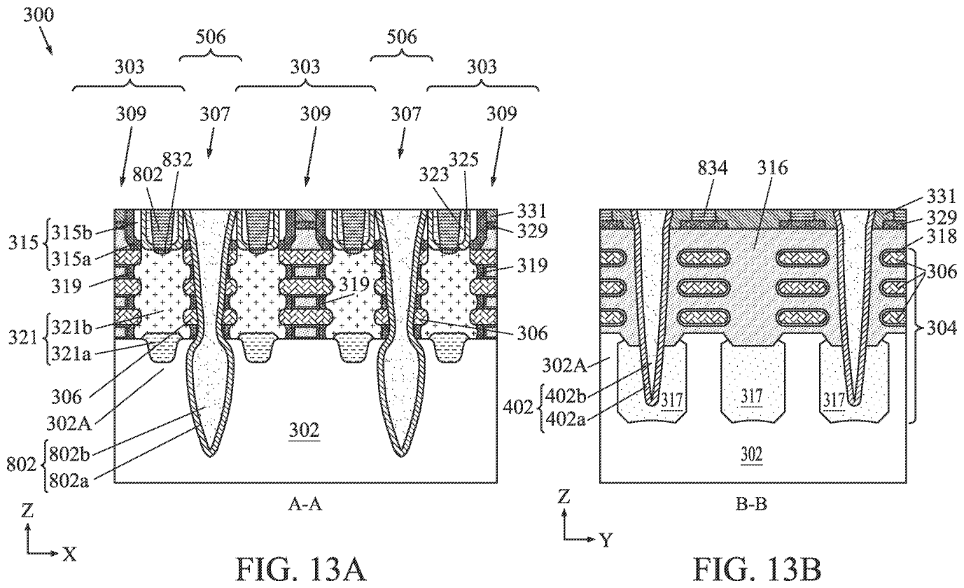

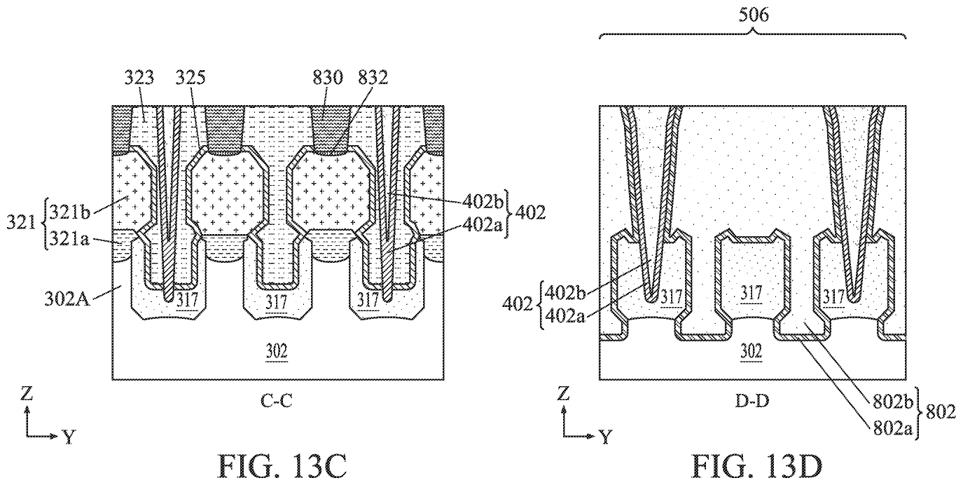

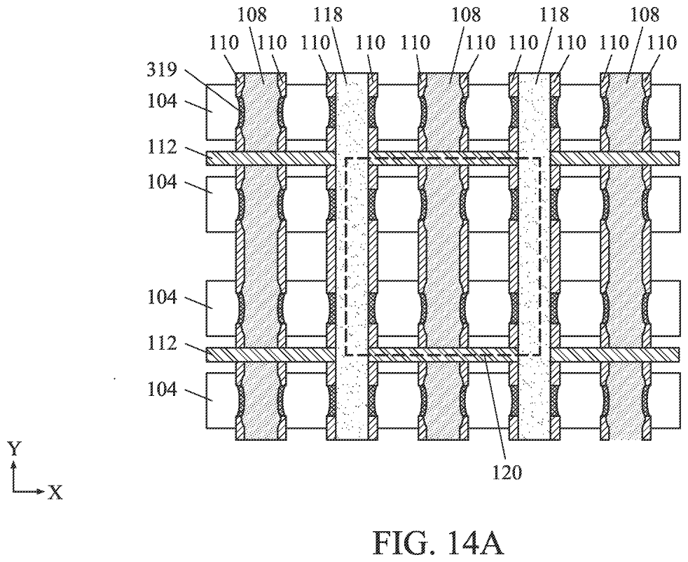

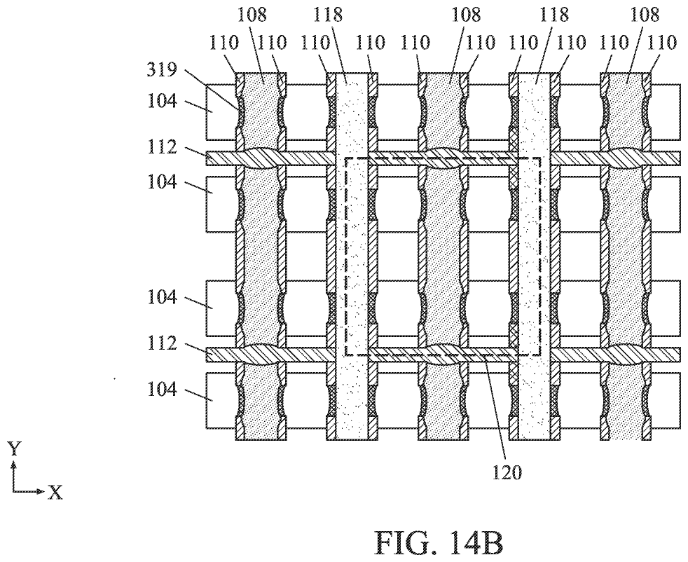

The formation of the CPO features 802 may be after the formation of the CMG features 402, as discussed above. Alternatively, the formation of the CMG features 402 may be after the formation of the CPO features 802. An exemplary resultant structure after block 216 is illustrated in FIGS. 13A-13D. Particularly referring to FIG. 13D, one difference is that the CMG features 402 are formed after the CPO features 802 and not covered by the CPO features 802. The top surfaces of the CMG features 402 and the CPO features 802 are coplanar (or termed as leveled). In other words, at each intersection, the CMG feature 402 divides the CPO feature 802 into segments.

Generally, the device 300 may undergo further processing to form various features and regions known in the art. For example, subsequent processing may form multilayer interconnect features (e.g., metal layers and interlayer dielectrics) on the substrate 302, configured to connect the various features to form a functional circuit that may include one or more multi-gate devices. Further, while the method 200 has been shown and described as including the device 300 having a GAA device, it will be understood that other device configurations are possible. In some embodiments, the method 200 may be used to fabricate FinFET devices or other multi-gate devices.

With respect to the description provided herein, disclosed are structures and related methods for performing a CMG process and a CPO process in forming cut-metal-gate (CMG) isolation features and cut-poly (CPO) isolation features, such as in form of a grid of cells and providing electrical isolation between adjacent source/drain features and adjacent metal gate structures. Embodiments of the present disclosure can be readily integrated into existing semiconductor manufacturing processes.

In one exemplary aspect, the present disclosure is directed to a method of fabricating a semiconductor device. The method includes providing a dummy structure including a plurality of channel layers disposed over a substrate, inner spacers disposed between adjacent ones of the plurality of channel layers, and a gate structure interposing the plurality of channel layers and extending lengthwise in a first direction, forming a first trench dividing the gate structure into segments, the first trench extending lengthwise in a second direction perpendicular to the first direction, depositing a first isolation feature in the first trench, etching the gate structure and the plurality of channel layers to form a second trench, the second trench extending lengthwise in the first direction and exposes the inner spacers, and depositing a second isolation feature in the second trench, the second isolation feature intersecting the first isolation feature in a top view of the semiconductor device. In some embodiments, the second isolation feature has a width larger than the first isolation feature. In some embodiments, the depositing of the first isolation feature is prior to the depositing of the second isolation feature. In some embodiments, the second isolation feature covers a top surface of the first isolation feature. In some embodiments, the depositing of the first isolation feature is after the depositing of the second isolation feature. In some embodiments, top surfaces of the first and second isolation features are coplanar. In some embodiments, a bottom portion of the second isolation feature is directly under a bottommost one of the inner spacers. In some embodiments, a bottom surface of the second isolation feature is below a bottom surface of the first isolation feature. In some embodiments, a bottom portion of the first isolation feature is embedded in a dielectric feature, and a portion of the second isolation feature is directly under the dielectric feature. In some embodiments, the forming of the first trench divides a merged source/drain epitaxial feature into two separated portions.

In another exemplary aspect, the present disclosure is directed to a method. The method includes forming a fin element over a substrate and extending lengthwise along a first direction, forming first, second, and third gate structures across the fin element, each of the first, second, and third gate structures extending lengthwise along a second direction perpendicular to the first direction, forming first and second trenches sandwiching the fin element and extending lengthwise in the first direction, each of the first and second trenches intersecting the first, second, and the third gate structures, forming first and second isolation features in the first and second trenches, respectively, and replacing the first and third gate structures with third and fourth isolation features, respectively. In some embodiments, in a top view, the first, second, third, and fourth isolation features form a cell fully surrounding an intersection of the second gate structure and the fin element. In some embodiments, the fin element includes a plurality of channel layers vertically stacked, and the second gate structure wraps each of the channel layers. In some embodiments, a width of the third and fourth isolation features is larger than a width of the first and second isolation features. In some embodiments, a depth of the third and fourth isolation features is larger than a depth of the first and second isolation features. In some embodiments, each of the third and fourth isolation features covers sidewalls and top surfaces of the first and second isolation features.

In another exemplary aspect, the present disclosure is directed to a semiconductor structure. The semiconductor structure device includes a plurality of channel layers stacked vertically above a substrate, a gate structure engaging the channel layers, the gate structure extending lengthwise along a first direction, a first isolation feature dividing the gate structure into two segments, the first isolation feature extending lengthwise along a second direction perpendicular to the first direction, and a second isolation feature extending lengthwise parallel to the gate structure, the second isolation feature intersecting the first isolation feature in a top view of the semiconductor device. In some embodiments, a width of the second isolation feature is larger than a width of the first isolation feature. In some embodiments, a depth of the second isolation feature is larger than a depth of the first isolation feature. In some embodiments, the second isolation feature has a necking profile in a cross-section of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a semiconductor device, comprising:
providing a dummy structure including a plurality of channel layers disposed over a substrate, inner spacers disposed between adjacent ones of the plurality of channel layers, and a gate structure interposing the plurality of channel layers and extending lengthwise in a first direction;
forming a first trench dividing the gate structure into segments, wherein the first trench extends lengthwise in a second direction perpendicular to the first direction;
depositing a first isolation feature in the first trench;
etching the gate structure and the plurality of channel layers to form a second trench, wherein the second trench extends lengthwise in the first direction and exposes the inner spacers; and
depositing a second isolation feature in the second trench, wherein the second isolation feature intersects the first isolation feature in a top view of the semiconductor device.

2. The method of claim 1, wherein the second isolation feature has a width larger than the first isolation feature.

3. The method of claim 1, wherein the depositing of the first isolation feature is prior to the depositing of the second isolation feature.

4. The method of claim 3, wherein the second isolation feature covers a top surface of the first isolation feature.

5. The method of claim 1, wherein the depositing of the first isolation feature is after the depositing of the second isolation feature.

6. The method of claim 5, wherein top surfaces of the first and second isolation features are coplanar.

7. The method of claim 1, wherein a bottom portion of the second isolation feature is directly under a bottommost one of the inner spacers.

8. The method of claim 1, wherein a bottom surface of the second isolation feature is below a bottom surface of the first isolation feature.

9. The method of claim 1, wherein a bottom portion of the first isolation feature is embedded in a dielectric feature, and a portion of the second isolation feature is directly under the dielectric feature.

10. The method of claim 1, wherein the forming of the first trench divides a merged source/drain epitaxial feature into two separated portions.

11. A method, comprising:
forming a fin element over a substrate and extending lengthwise along a first direction;
forming first, second, and third gate structures across the fin element, each of the first, second, and third gate structures extending lengthwise along a second direction perpendicular to the first direction;
forming first and second trenches sandwiching the fin element and extending lengthwise in the first direction, each of the first and second trenches intersecting the first, second, and the third gate structures;
forming first and second isolation features in the first and second trenches, respectively; and
replacing the first and third gate structures with third and fourth isolation features, respectively.

12. The method of claim 11, wherein, in a top view, the first, second, third, and fourth isolation features form a cell fully surrounding an intersection of the second gate structure and the fin element.

13. The method of claim 12, wherein the fin element includes a plurality of channel layers vertically stacked, and the second gate structure wraps each of the channel layers.

14. The method of claim 11, wherein a width of the third and fourth isolation features is larger than a width of the first and second isolation features.

15. The method of claim 11, wherein a depth of the third and fourth isolation features is larger than a depth of the first and second isolation features.

16. The method of claim 11, wherein each of the third and fourth isolation features covers sidewalls and top surfaces of the first and second isolation features.

17. A semiconductor device, comprising:
a plurality of channel layers stacked vertically above a substrate;
a gate structure engaging the channel layers, the gate structure extending lengthwise along a first direction;
a first isolation feature dividing the gate structure into two segments, the first isolation feature extending lengthwise along a second direction perpendicular to the first direction; and
a second isolation feature extending lengthwise parallel to the gate structure, the second isolation feature intersecting the first isolation feature in a top view of the semiconductor device.

18. The semiconductor device of claim 17, wherein a width of the second isolation feature is larger than a width of the first isolation feature.

19. The semiconductor device of claim 17, wherein a depth of the second isolation feature is larger than a depth of the first isolation feature.

20. The semiconductor device of claim 17, wherein the second isolation feature has a necking profile in a cross-section of the semiconductor device.
